(19) United States
(12) Patent Application Publication
(10) Pub. No.: US 2013/0146136 A1
(43) Pub. Date: Jun. 13, 2013

(54) PHOTOVOLTAIC DEVICE AND METHOD OF MANUFACTURING THE SAME

(71) Applicants: Kyoung-Jin SEO, Yongin-si (KR); Jeong-Byong GOOK, Yongin-si (KR); Hyun-Jong KIM, Yongin-si (KR); Min PARK, Yongin-si (KR); Czang-Ho LEE, Yongin-si (KR); Sang-Won LEE, Yongin-si (KR)

(72) Inventors: Kyoung-Jin SEO, Yongin-si (KR); Jeong-Byong GOOK, Yongin-si (KR); Hyun-Jong KIM, Yongin-si (KR); Min PARK, Yongin-si (KR); Czang-Ho LEE, Yongin-si (KR); Sang-Won LEE, Yongin-si (KR)

(21) Appl. No.: 13/587,393

(22) Filed: Aug. 16, 2012

Related U.S. Application Data
(60) Provisional application No. 61/569,956, filed on Dec. 13, 2011.

(51) Int. Cl. H01L 31/0236; H01L 31/18

(52) U.S. Cl. 136/256; 438/72; 257/E31.127

(57) ABSTRACT

A photovoltaic device and a method of manufacturing the same, the device including a semiconductor substrate having a first surface and a second surface opposite to the first surface; a silicon nitride gap insulation layer on the first surface of the semiconductor substrate, a portion of the gap insulation layer proximate to the semiconductor substrate having a silicon:nitrogen ratio different from a silicon:nitrogen ratio in a portion of the gap insulation layer distal to the semiconductor substrate; a semiconductor structure on the first surface of the semiconductor substrate; and an electrode on the semiconductor structure.

### CROSS-REFERENCE TO RELATED APPLICATION

The present application claims priority under 35 U.S.C. §119(e) to U.S. Provisional Application No. 61/569,956, filed on Dec. 13, 2011, and entitled: “Photovoltaic Device,” which is incorporated herein by reference in its entirety.

### BACKGROUND

1. Field

Embodiments relate to a photovoltaic device and a method of manufacturing the same.

2. Description of the Related Art

In order to manufacture a photovoltaic device, a p-n junction may be formed by doping an n-type (or p-type) dopant into a p-type (or n-type) substrate so as to form an emitter. Electron-hole pairs formed by receiving light may be separated, and electrons may be collected by an electrode of an n-type area and holes may be collected by an electrode of a p-type area, thereby generating electric power.

### SUMMARY

Embodiments are directed to a photovoltaic device and a method of manufacturing the same.

The embodiments may be realized by providing a photovoltaic device including a semiconductor substrate having a first surface and a second surface opposite to the first surface; a silicon nitride gap insulation layer on the first surface of the semiconductor substrate, a portion of the gap insulation layer proximate to the semiconductor substrate having a silicon:nitrogen ratio different from a silicon:nitrogen ratio in a portion of the gap insulation layer distal to the semiconductor substrate; a semiconductor structure on the first surface of the semiconductor substrate; and an electrode on the semiconductor structure.

The portion of the gap insulation layer proximate to the semiconductor substrate may have a refractive index of about 1.98 or greater, and the portion of the gap insulation layer distal to the semiconductor substrate may have a refractive index of about 1.96 or less.

The silicon:nitrogen ratio of the portion of the gap insulation layer proximate to the semiconductor substrate may be greater than the silicon:nitrogen ratio of the portion of the gap insulation layer distal to the semiconductor substrate.

The silicon:nitrogen ratio of the portion of the gap insulation layer proximate to the semiconductor substrate may be 0.75 or higher, and the silicon:nitrogen ratio of the portion of the gap insulation layer distal to the semiconductor substrate may be less than 0.75.

The silicon:nitrogen ratio of the gap insulation layer may be continuous along a thickness direction thereof.

The gap insulation layer may include a first gap insulation layer on the first surface of the semiconductor substrate, and a second gap insulation layer on the first gap insulation layer, the first gap insulation layer being between the second gap insulation layer and the semiconductor substrate.

The first gap insulation layer may have a silicon:nitrogen ratio greater than a silicon:nitrogen ratio of the second gap insulation layer.

The silicon:nitrogen ratio of the first gap insulation layer may be 0.75 or greater, and the silicon:nitrogen ratio of the second gap insulation layer may be less than 0.75.

The first gap insulation layer may have a refractive index of about 1.98 or greater, and the second gap insulation layer may have a refractive index of about 1.96 or less.

The device may further include at least one of a passivation layer and an antireflection layer on the second surface of the semiconductor substrate.

The embodiments may also be realized by providing a method of manufacturing a photovoltaic device, the method including providing a semiconductor substrate; forming a silicon nitride gap insulation layer on a first surface of the semiconductor substrate such that a portion of the gap insulation layer proximate to the semiconductor substrate has a silicon:nitrogen ratio different from a silicon:nitrogen ratio in a portion of the gap insulation layer distal to the semiconductor substrate.

The portion of the gap insulation layer proximate to the semiconductor substrate may have a refractive index of about 1.98 or greater, and the portion of the gap insulation layer distal to the semiconductor substrate may have a refractive index of about 1.96 or less.

The silicon:nitrogen ratio of the portion of the gap insulation layer proximate to the semiconductor substrate may be greater than the silicon:nitrogen ratio of the portion of the gap insulation layer distal to the semiconductor substrate.

The silicon:nitrogen ratio of the portion of the gap insulation layer proximate to the semiconductor substrate may be 0.75 or greater, and the silicon:nitrogen ratio of the portion of the gap insulation layer distal to the semiconductor substrate may be less than 0.75.

The silicon:nitrogen ratio of the gap insulation layer may be continuous along a thickness direction thereof.

Forming the gap insulation layer may include forming a first gap insulation layer on the first surface of the semiconductor substrate, and forming a second gap insulation layer on the first gap insulation layer such that the first gap insulation layer is between the second gap insulation layer and the semiconductor substrate.

The first gap insulation layer may have a silicon:nitrogen ratio greater than a silicon:nitrogen ratio of the second gap insulation layer.

The silicon:nitrogen ratio of the first gap insulation layer may be 0.75 or greater, and the silicon:nitrogen ratio of the second gap insulation layer may be less than 0.75.

The first gap insulation layer may have a refractive index of about 1.98 or greater, and the second gap insulation layer may have a refractive index of about 1.96 or less.

The method may further include forming at least one of a passivation layer and an antireflection layer on a second surface of the semiconductor substrate, the second surface being opposite to the first surface.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a photovoltaic device according to an embodiment.

FIG. 2 illustrates a flowchart describing a method of manufacturing a photovoltaic device according to an embodiment.

FIGS. 3A through 3K illustrate cross-sectional views of stages in the method of FIG. 2.

FIG. 4 illustrates a graph showing an etching amount of an alkaline solution and an etching amount of an acidic solution according to a refractive index of a silicon nitride layer.

FIGS. 5A through 5D illustrate cross-sectional views of stages in a texturing operation of a method of manufacturing a photovoltaic device according to a comparative example.

FIG. 6 illustrates a cross-sectional view of a photovoltaic device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The terminology used herein is for the purpose of describing particular embodiments only and is not intended to be limiting of exemplary embodiments. As used herein, the singular forms “a/an” and “the” are intended to include the plural forms (a plurality of) as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof. The terms such as “first” and “second” are used herein merely to describe a variety of constituent elements, but the constituent elements are not limited by the terms. The terms are used only for the purpose of distinguishing one constituent element from another constituent element.

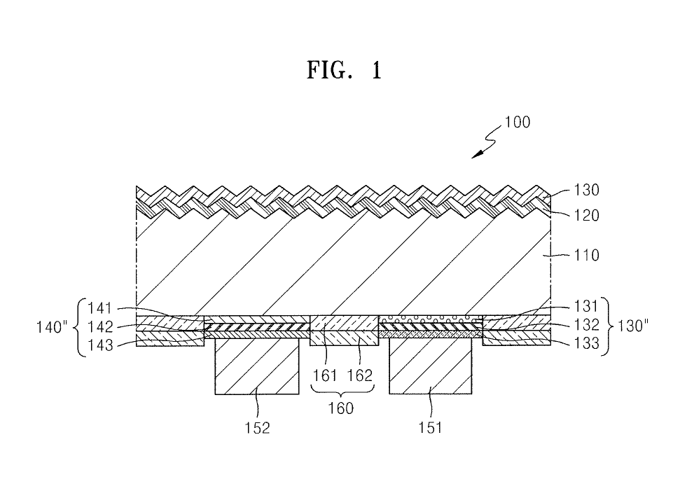

FIG. 1 illustrates a cross-sectional view of a photovoltaic device 100 according to an embodiment.

Referring to FIG. 1, the photovoltaic device 100 according to the present embodiment may include a semiconductor substrate 110, a passivation layer 120 and an anti-reflection layer 130 on a front surface of the semiconductor substrate 110, a first semiconductor structure 130″ (of a first conductive type) and a second semiconductor structure 140″ (of a second conductive type) on a back surface of the semiconductor substrate 110, first and second electrodes 151 and 152 respectively on the first semiconductor structure 130″ and the second semiconductor structure 140″, and a gap insulation layer 160 between the first and second electrodes 151 and 152. The gap insulation layer 160 may include a first gap insulation layer 161 and a second gap insulation layer 162. The first and second gap insulation layers 161 and 162 may include a silicon nitride layer in which contents of silicon and nitrogen are different from each other. For example, a silicon:nitrogen ratio of the first gap insulation layer 161, e.g., a portion of the gap insulation layer 160 proximate to the semiconductor substrate 110, may be different from a silicon:nitrogen ratio of the second gap insulation layer 162, e.g., a portion of the gap insulation layer 160 distal to the semiconductor substrate 110. The gap insulation layer 160, e.g., the first gap insulation layer 161, may help improve efficiency of collection of carriers by preventing surface recombination of carriers generated by the semiconductor substrate 110.

The semiconductor substrate 110 may include a crystalline silicon substrate, e.g., a monocrystalline silicon substrate. In an implementation, the semiconductor substrate 110 may be a monocrystalline silicon substrate of an n-type conductive type. Although in the following description the semiconductor substrate 110 is described as being a monocrystalline silicon substrate of an n-type conductive type, the embodiments are not limited thereto. For example, the semiconductor substrate 110 may be a monocrystalline silicon substrate of a p-type conductive type.

The semiconductor substrate 110 may have a first surface and a second surface that is opposite to the first surface. The second surface may be the front surface, e.g., a light-receiving surface. Emitter and base electrodes (first and second electrodes 151 and 152) may be provided on the first surface, e.g., the back surface. To increase a light path of incident light and help improve efficiency of absorbing light, a texture structure, e.g., a textured pattern, including an uneven pattern may be formed on the second surface. The textured pattern may be an uneven surface including a plurality of minute protrusions and may decrease reflectance of the incident light.

The passivation layer 120 may be on the second surface of the semiconductor substrate 110 and may help improve efficiency of collection of carriers by preventing surface recombination of carriers generated by the semiconductor substrate 110. For example, the passivation layer 120 may help reduce surface recombination loss (caused by a defect of a surface of the semiconductor substrate 110) and may help improve the carrier collection efficiency.

The passivation layer 120 may be an intrinsic semiconductor layer, a doped semiconductor layer, a silicon oxide layer, or a silicon nitride layer. The intrinsic semiconductor layer or the doped semiconductor layer may be formed of amorphous silicon deposited on the semiconductor substrate 110. For example, the passivation layer 120 may be formed of amorphous silicon doped with a dopant or impurity of a first conductive type (e.g., the same conductive type as the semiconductor substrate 110). Also, the passivation layer 120 may be doped at a higher concentration than that of the semiconductor substrate 110 so as to form a front surface field (FSF) for preventing the surface recombination.

The anti-reflection layer 130 may be formed on the passivation layer 120. The passivation layer 130 may help prevent light absorption loss due to reflection of light when sunlight is incident. The anti-reflection layer 130 may include a silicon oxide layer or a silicon nitride layer. For example, the anti-reflection layer 130 may be formed as a single layer of a silicon oxide layer or a combined layer of a silicon oxide layer and a silicon nitride layer having different refractive indexes.

The passivation layer 120 and the anti-reflection layer 130 may be formed as separate layers, but the present embodiments are not limited thereto. In an implementation, the passivation layer 120 and the anti-reflection layer 130 may be formed as one layer. For example, a silicon nitride layer may be formed so that effects of passivation and anti-reflection may be simultaneously obtained.

The first and second semiconductor structures 130″ and 140″ (having opposite conductive types) may be formed on the first surface of the semiconductor substrate 110. The first and second semiconductor structures 130″ and 140″ may respectively form an emitter and a base that separate and collect the carriers generated from the semiconductor substrate 110.

The first semiconductor structure 130″ may include a first intrinsic semiconductor layer 131, a first conductive type semiconductor layer 132, and a first transparent conductive layer 133, which may be sequentially deposited on the semiconductor substrate 110. The first intrinsic semiconductor layer 131 and the first conductive type semiconductor layer 132 may be formed of amorphous silicon (a-Si) or microcrystalline silicon (μc-Si).

The first intrinsic semiconductor layer 131 may be formed by not doping a dopant or impurity or only doping a small amount of dopant or impurity. For example, the first intrinsic semiconductor layer 131 may passivate a surface of the semiconductor substrate 110 to help prevent recombination of the carrier generated from the semiconductor substrate 110, and may help improve interface characteristics between the semiconductor substrate 110 (formed of crystalline silicon) and the first conductive type semiconductor layer 132 (formed of amorphous silicon).

The first conductive type semiconductor layer 132 may be formed by doping a p-type dopant or impurity. The first conductive type semiconductor layer 132 may form a p-n junction with the semiconductor substrate 110. The first conductive type semiconductor layer 132 may form an emitter for collecting minority carrier, e.g., holes, from the n-type semiconductor substrate 110.

The first transparent conductive layer 133 may include a material that is electrically conductive and optically transparent. For example, the first transparent conductive layer 133 may be formed of transparent conductive oxide (TCO) such as indium tin oxide (ITO) or indium zinc oxide (IZO). The first transparent conductive layer 133 may help reduce contact resistance with the first electrode 151 and may help mediate a connection between the first conductive type semiconductor layer 132 and the first electrode 151. The first electrode 151 may include, e.g., silver (Ag), gold (Au), copper (Cu), aluminum (Al), and/or an alloy thereof.

The second semiconductor structure 140″ may include a second intrinsic semiconductor layer 141, a second conductive type semiconductor layer 142, and a second transparent conductive layer 143, which may be sequentially deposited on the semiconductor substrate 110. The second intrinsic semiconductor layer 141 and the second conductive type semiconductor layer 142 may be formed of amorphous silicon (a-Si) or microcrystalline silicon (μc-Si).

The second intrinsic semiconductor layer 141 may be formed by not doping a dopant or impurity or only doping a small amount of dopant or impurity. For example, the second intrinsic semiconductor layer 141 may passivate a surface of the semiconductor substrate 110 to help prevent recombination of the carrier generated from the semiconductor substrate 110, and may help improve interface characteristics between the semiconductor substrate 110 (formed of crystalline silicon) and the second conductive type semiconductor layer 142 (formed of amorphous silicon).

The second conductive type semiconductor layer 142 may be formed by doping an n-type dopant. The second conductive type semiconductor layer 142 may form a base for collecting minority carriers, e.g., electrons, from the n-type semiconductor substrate 110.

The second transparent conductive layer 143 may include a material that is electrically conductive and optically transparent. For example, the second transparent conductive layer 143 may be formed of transparent conductive oxide (TCO) such as indium tin oxide (ITO) or indium zinc oxide (IZO). The second transparent conductive layer 143 may help reduce contact resistance with the second electrode 152 and may help mediate a connection between the second conductive type semiconductor layer 142 and the second electrode 152. The second electrode 152 may include, e.g., silver (Ag), gold (Au), copper (Cu), aluminum (Al), and/or an alloy thereof.

As described above, the first and second semiconductor structures 130″ and 140″ (forming an emitter and a base) may respectively include the first and second intrinsic semiconductor layers 131 and 141, the first and second conductive type semiconductor layers 132 and 142, and the first and second transparent conductive layers 133 and 143. However, the embodiments are not limited thereto. In an implementation, the first and second semiconductor structures 130″ and 140″ may not include the first and second intrinsic semiconductor layers 131 and 141. In an implementation, the first and second semiconductor structures 130″ and 140″ may not include the first and second transparent conductive layers 133 and 143.

The gap insulation layer 160 may be between the emitter and the base, e.g., the first semiconductor structure 130″ and the second semiconductor structure 140″, respectively. The gap insulation layer 160 may include the first and second gap insulation layers 161 and 162. The first gap insulation layer 161 may be formed on the first surface of the semiconductor substrate 110. The second gap insulation layer 162 may be formed on, e.g., directly on, the first gap insulation layer 161. The first and second gap insulation layers 161 and 162 may be silicon nitride layers. A composition ratio (a:b) of silicon (Si) and nitrogen (N) forming the first gap insulation layer (SiₐN_{b}) 161 may be different from a composition ratio (c:d) of silicon and nitrogen forming the second gap insulation layer (Si_{c}N_{d}) 162. For example, the silicon:nitrogen ratio of the first gap insulation layer 161 may be different from the silicon:nitrogen ration of the second gap insulation layer 162.

The first gap insulation layer (SiₐN_{b}) 161 may be a silicon nitride layer having a relatively higher silicon content than that of the second gap insulation layer 162. The second gap insulation layer (Si_{c}N_{d}) 162 may be a silicon nitride layer having a relatively higher nitrogen content than that of the first gap insulation layer 161.

For example, the first gap insulation layer 161 may have a silicon content greater than or equal to that of a stoichiometric silicon nitride layer (Si₃N₄). In an implementation, the first gap insulation layer 161 may have a silicon content greater than that of a stoichiometric silicon nitride layer (Si₃N₄). The second gap insulation layer 162 may have a higher nitrogen content than that of a stoichiometric silicon nitride layer (Si₃N₄). For example, the composition ratio (a/b) or silicon:nitrogen ratio of the first gap insulation layer 161 may be greater than or equal to 0.75 (i.e., the composition ratio (Si/N) or silicon:nitrogen ratio of silicon to nitrogen of stoichiometric silicon nitride). The composition ratio (c/d) or silicon:nitrogen ratio of the second gap insulation layer 162 may be less than 0.75.

The content of silicon may be a factor that affects a refractive index of the silicon nitride layer. For example, as the content of silicon increases in a silicon nitride layer, the refractive index likewise increases. The refractive index of the first gap insulation layer 161 may be about 1.98 or greater, e.g., about 2.0 or greater. The refractive index of the second gap insulation layer 162 may be about 1.96 or less.

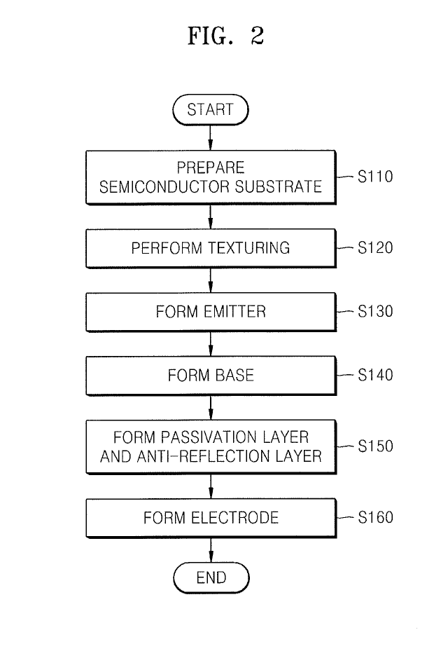

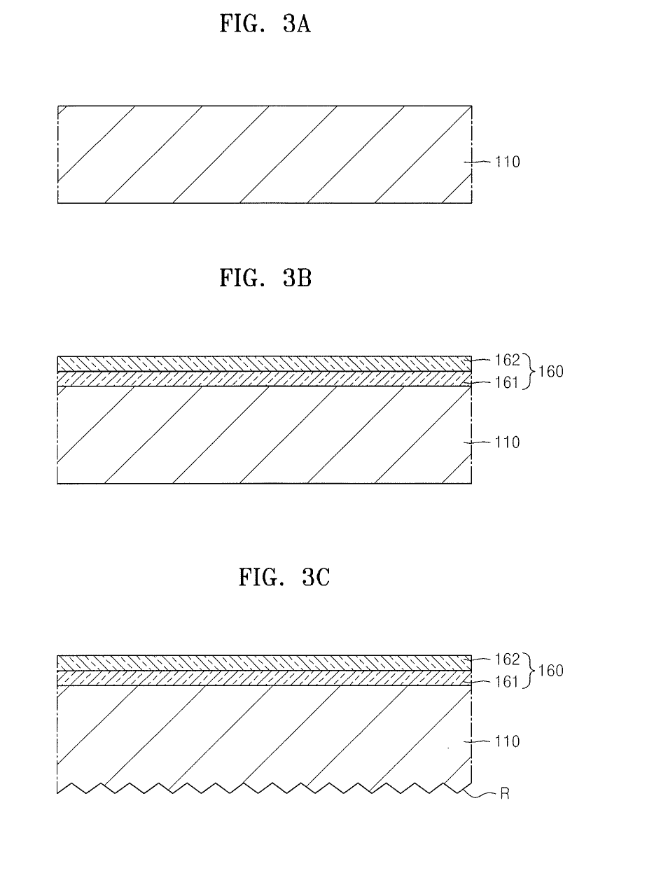

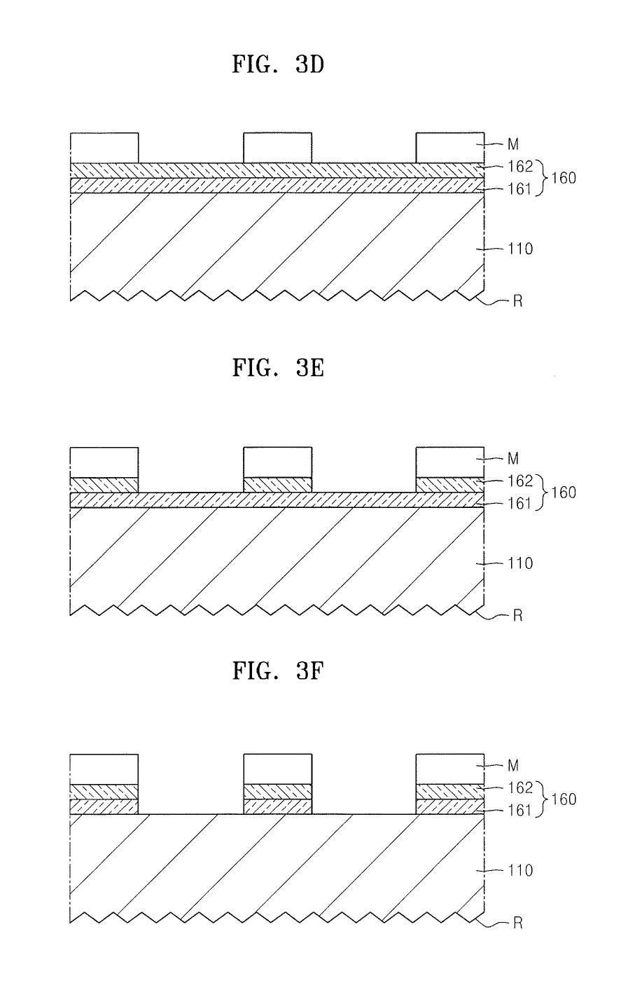

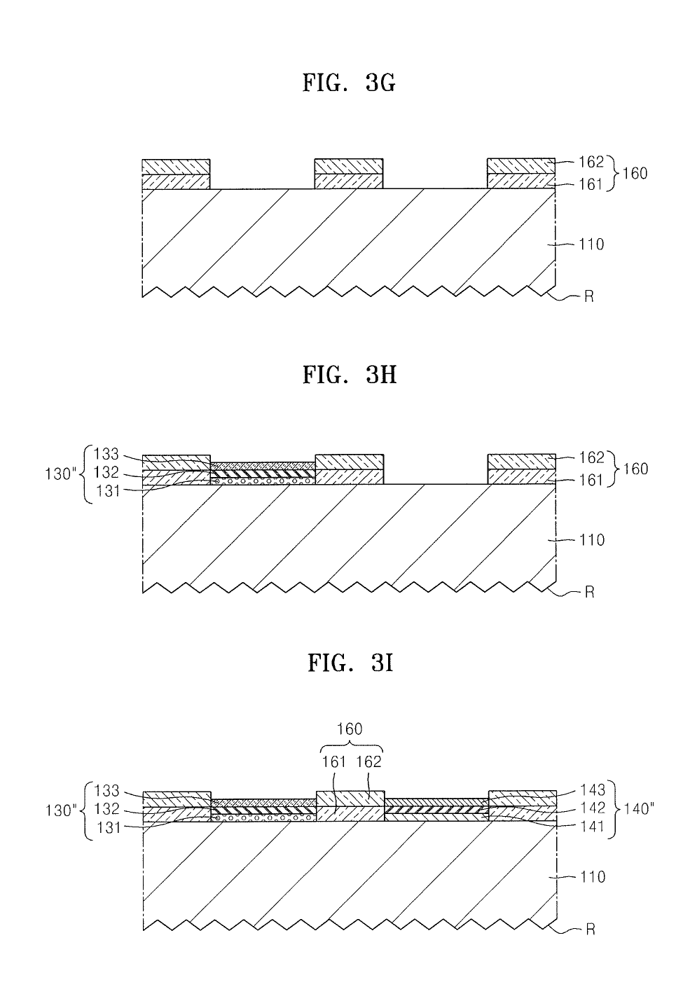

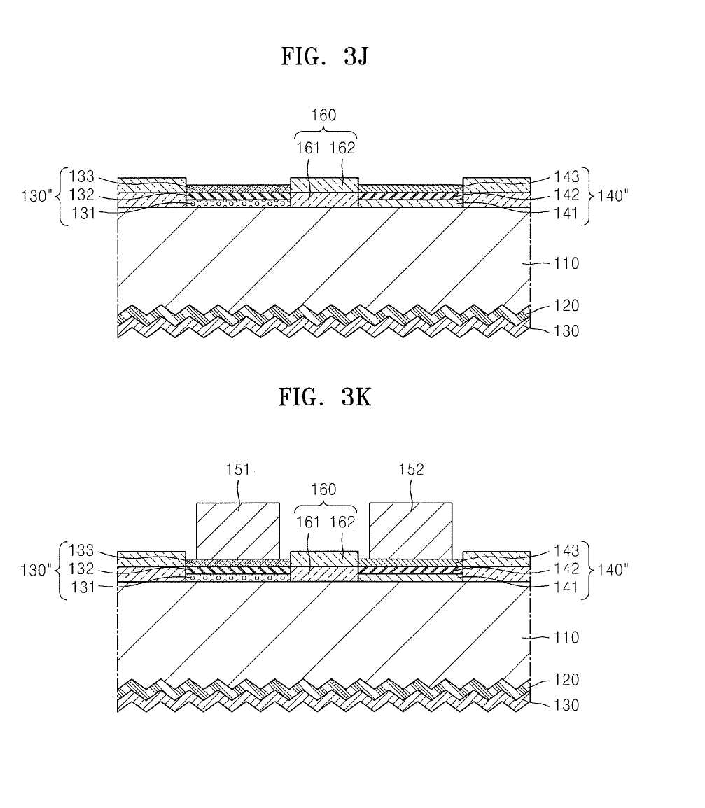

A method of manufacturing a photovoltaic device according to an embodiment will now be described with reference to FIGS. 2 and 3A through 3K.

FIG. 2 illustrates a flowchart describing a method of manufacturing a photovoltaic device according to an embodiment. FIGS. 3A through 3K illustrate cross-sectional views of stages in the method of FIG. 2.

In S110, the semiconductor substrate 110 may be prepared (see FIG. 3A). The semiconductor substrate 110 may be a monocrystalline silicon substrate. The semiconductor substrate 110 may have an n-type (or p-type) conductivity.

In S120, a silicon nitride (gap insulation) layer 160 may be formed on the first surface of the semiconductor substrate 110.

Referring to FIG. 3B, the silicon nitride (gap insulation) layer 160 may be formed on the first surface of the semiconductor substrate 110. The silicon nitride layer 160 may include the first and second silicon nitride layers 161 and 162. For example, the composition ratio (a:b) of silicon (Si) and nitrogen (N), e.g., the silicon:nitrogen ration, of the first silicon nitride layer (SiₐN_{b}) 161 may be different from the composition ratio (c:d) of silicon and nitrogen, e.g., the silicon:nitrogen ratio, of the second silicon nitride layer (Si_{c}N_{d}) 162.

For example, the first silicon nitride layer (SiₐN_{b}) 161 may have a relatively higher silicon content than that of the second silicon nitride layer 162. The second silicon nitride layer (Si_{c}N_{d}) 162 may have a relatively higher nitrogen content than that of the first silicon nitride layer 161.

For example, the first silicon nitride layer 161 may have silicon content greater than or equal to that of a stoichiometric silicon nitride layer (Si₃N₄). The second silicon nitride layer 162 may have a higher nitrogen content than that of a stoichiometric silicon nitride layer (Si₃N₄). For example, the composition ratio (a/b), e.g., the silicon:nitrogen ration, of the first silicon nitride layer 161 may be 0.75 or greater (i.e., the composition ratio (Si/N) of silicon and nitrogen of the stoichiometric silicon nitride layer). The composition ratio (c/d), e.g., the silicon:nitrogen ratio, of the second silicon nitride layer 162 may be less than 0.75.

The first and second silicon nitride layers 161 and 162 may be formed by a plasma enhanced chemical vapor deposition (PE-CVD) method. During PE-CVD, contents of nitrogen (N) and silicon (Si) may be adjusted. For example, the first and second silicon nitride layers 161 and 162 may be formed by adjusting flow rates of a gas that is a supply source of silicon and a gas that is a supply source of nitrogen.

The refractive index of the first silicon nitride layer 161 formed by the above-described method may be about 1.98 or greater, e.g., about 2.0 or greater. The refractive index of the second silicon nitride layer 162 formed by the above-described method may be about 1.96 or less.

In S130, a texturing process of forming an uneven pattern Ron the second surface of the semiconductor substrate 110 may be performed.

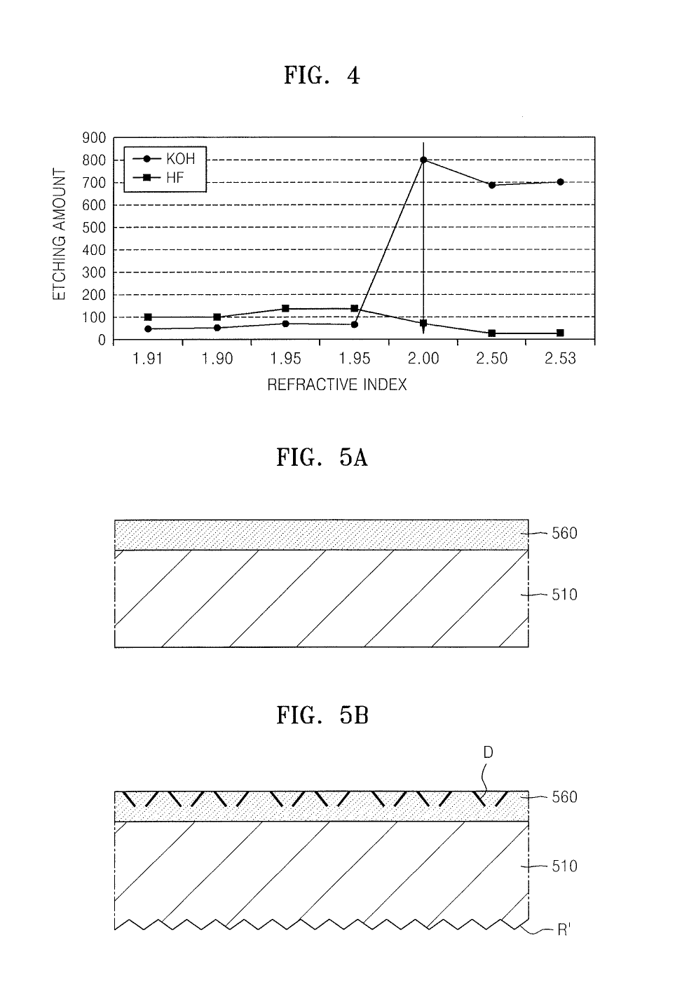

Referring to FIG. 3C, the uneven or textured pattern R may be formed on the second surface of the semiconductor substrate 110 using the silicon nitride layer 160, e.g., the second silicon nitride layer 162, as a mask. Referring to FIG. 4, the second silicon nitride layer 162 (having a relatively high nitrogen content) may characteristically have a strong resistance to an alkaline solution. Thus, the second silicon nitride layer 162 (formed on the second surface of the semiconductor substrate 110) may function as an etch mask during texturing for forming the uneven or textured pattern R on the first surface of the semiconductor substrate 110. An alkaline solution such as KOH, NaOH, or tetramethylammonium (TMAH) may be used as a texturing etchant.

Referring to FIG. 3D, an anti-etching layer M may be formed on the second silicon nitride layer 162. The anti-etching layer M may be an organic layer. The anti-etching layer M may be formed on the second silicon nitride layer 162 to cover an area of the second silicon nitride layer 162 except for an area where an emitter and a base, which will be described later, are to be formed.

Referring to FIG. 3E, the second silicon nitride layer 162 may be etched using the anti-etching layer M as a mask. The second silicon nitride layer 162 (having a relatively high nitrogen content) may characteristically have a strong resistance to an alkaline solution and weak resistance to an acidic solution, as described above. Accordingly, to etch the second silicon nitride layer 162 (that is not protected by the anti-etching layer), an acidic solution, e.g., hydrofluoric acid (HF) or nitric acid (HNO₃), may be used as an etchant. The first silicon nitride layer 161 (under the second silicon nitride layer 162) may not be damaged, because the first silicon nitride layer 161 may characteristically have a strong resistance to an acidic solution.

Referring to FIG. 3F, the first silicon nitride layer 161 may be etched using the anti-etching layer M as a mask. The etchant may etch the first silicon nitride layer 161. For example, the etchant may include a mixed solution of hydrofluoric acid (HF), nitric acid (HNO₃), and acetic acid. Alternatively, the etchant may include a mixed solution of hydrofluoric acid (HF), nitric acid (HNO₃), and deionized water (DIW). As noted above, the first silicon nitride layer 161 may characteristically have a relatively strong resistance to acid. Thus, an area of the first silicon nitride layer 161 (that is not protected by the anti-etching layer M) may be selectively removed by adopting sufficient concentration and time for removing the first silicon nitride layer 161. Referring to FIG. 3G, the anti-etching layer M may be removed. The anti-etching layer M may be removed by using an ethanol or acetone based solution.

According to the above-described operations, when the first and second silicon nitride layers 161 and 162 are removed by using the anti-etching layer M as a mask, a partial area of the first surface of the semiconductor substrate 110 may be exposed. In an operation that will be described later, an emitter region and a base region may be formed on a first area and a second area of the partial area of the first surface of the semiconductor substrate 110, respectively. The first and second silicon nitride layers 161 and 162 (disposed between the emitter region and the base region) may become a gap insulation layer 160.

In S140, the first semiconductor structure 130″ may be formed in the first region of the second surface of the semiconductor substrate 110.

Referring to FIG. 3H, the first semiconductor structure 130″ may be formed on the first area of the first surface of the semiconductor substrate 110. The first semiconductor structure 130″ may include the first intrinsic semiconductor layer 131, the first conductive type semiconductor layer 132, and the first transparent conductive layer 133.

The first intrinsic semiconductor layer 131 and the first conductive type semiconductor layer 132 may include amorphous silicon (a-Si) or microcrystalline silicon (μc-Si). The first transparent conductive layer 133 may include a material that is electrically conductive and optically transparent.

In an implementation, the first intrinsic semiconductor layer 131 and the first conductive type semiconductor layer 132 may be formed by applying a CVD method in a state in which the second region of the first surface of the semiconductor substrate 110 is protected by a mask (not shown). The first transparent conductive layer 133 may be formed by a method such as sputtering, e-beam, evaporation, or the like.

In S150, the second semiconductor structure 140″ may be formed in the second region of the first surface of the semiconductor substrate 110.

Referring to FIG. 31, the second semiconductor structure 140″ may be formed in the second region of the first surface of the semiconductor substrate 110. The second semiconductor structure 140″ may include the second intrinsic semiconductor layer 141, the second conductive type semiconductor layer 142, and the second transparent conductive layer 143.

The second intrinsic semiconductor layer 141 and the second conductive type semiconductor layer 142 may include amorphous silicon (a-Si) or microcrystalline silicon (μc-Si). The second transparent conductive layer 143 may include a material that is electrically conductive and optically transparent.

In an implementation, the first and second semiconductor substrates 130″ and 140″ may include the first and second intrinsic semiconductor layers 131 and 141, the first and second conductive type semiconductor layers 132 and 142, and the first and second transparent conductive layers 133 and 143. However, the embodiments are not limited thereto. In an implementation, the first and second semiconductor substrates 130″ and 140″ may not include the first and second intrinsic semiconductor layers 131 and 141. In an implementation, the first and second semiconductor substrates 130″ and 140″ may not include the first and second transparent conductive layers 133 and 143.

In S160, the passivation layer 120 and the anti-reflection layer 130 may be formed. Prior to the formation of the passivation layer 120 and the anti-reflection layer 130, the semiconductor substrate 110 may be cleaned for effective passivation.

Referring to FIG. 3J, the passivation layer 120 and the anti-reflection layer 130 may be formed on the second surface of the semiconductor substrate 110.

The passivation layer 120 may be formed by a CVD method, e.g., a CVD method using silane (SiH₄), a silicon containing gas. The passivation layer 120 may be formed on the second surface, e.g., a light-receiving surface, of the semiconductor substrate 110. Thus, a band gap may be adjusted to reduce light absorption. For example, the band gap may be increased by adding an additive so that light absorption may be reduced and thus incident light may be absorbed in the semiconductor substrate 110.

The anti-reflection layer 130 may be formed as a silicon oxide layer or a silicon nitride layer. For example, the anti-reflection layer 130 may be formed as a single layer of a silicon oxide layer or a combination layer of a silicon oxide layer and a silicon nitride layer having different refractive indexed. The anti-reflection layer 130 may be formed by a CVD method, sputtering, spin coating, or the like.

The passivation layer 120 and the anti-reflection layer 130 may be formed as separated layers. However, the embodiments are not limited thereto. In an implementation, a silicon nitride layer capable of simultaneously performing functions of the passivation layer 120 and the anti-reflection layer 130 may be formed.

In S170, the first and second electrodes 151 and 152 may be formed.

Referring to FIG. 3K, the first and second electrodes 151 and 152 may be respectively formed on the first and second semiconductor structures 130″ and 140″. For example, the first and second electrodes 151 and 152 may be formed by coating paste including silver (Ag), copper (Cu), aluminum (Al), and/or an alloy thereof and then firing the same. In an implementation, the first and second electrodes 151 and 152 may be formed by performing a method such as electroplating after an electrode seed (not shown) is formed.

According to the method of manufacturing a photovoltaic device described with reference to FIGS. 2 and 3A through 3K, a silicon nitride layer (e.g., the gap insulation layer 160) may include the first and second silicon nitride layers 161 and 162 having different compositions. Texturing may be performed by using the silicon nitride layer 162 as a mask, and a partial area of the silicon nitride layers 161 and 162 may be removed by selective etching so that a high quality gap insulation layer 160 (see FIG. 1) may be formed. The above-described characteristics of the embodiments will be clearly disclosed through the explanation of a method of manufacturing a photovoltaic device according to a comparative example that is described below.

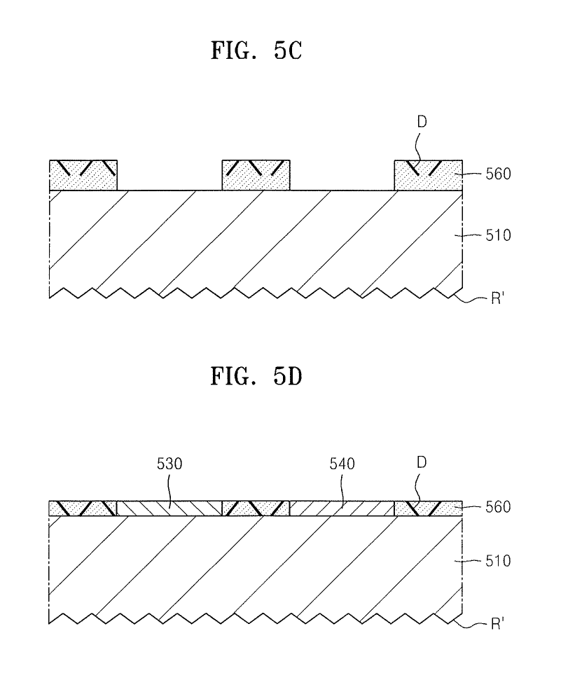

FIGS. 5A through 5D illustrate cross-sectional views of stages in a texturing operation of a method of manufacturing a photovoltaic device according to a comparative example.

While the silicon nitride layer 160 according to an embodiment may include the first and second silicon nitride layers 161 and 162 having different compositions, a silicon nitride layer 560 according to a comparative example may be a silicon nitride layer having a composition of Si₃N₄.

Referring to FIG. 5A, the silicon nitride layer 560 (having a composition of Si₃N₄) may be formed on a semiconductor substrate 510. The silicon nitride layer 560 may be formed on a first surface, e.g., a back side of a light-receiving surface, of the semiconductor substrate 510.

Referring to FIG. 5B, an uneven pattern R′ may be formed on a second surface of the semiconductor substrate 510 using the silicon nitride layer 560 as a mask. An alkaline solution, e.g., KOH, NaOH, or tetramethylammonium (TMAH), may be used as a texturing etchant.

Although the silicon nitride layer 560 having a composition of Si₃N₄ according to the comparative example may protect the first surface of the semiconductor substrate 510 to a degree, the silicon nitride layer 560 itself may be damaged by the alkaline solution so that damage D may be generated.

Referring to FIGS. 5C and 5D, after an anti-etching layer (not shown) may be formed on the silicon nitride layer 560 and a part of the silicon nitride layer 560 is etched, the first and second semiconductor structures 530 and 540 may be formed in emitter and base regions, respectively.

According to the method of manufacturing a photovoltaic device according to the comparative example, the damage D may be generated in the silicon nitride layer 560. Thus, the function of the gap insulation layer 560 between the first and second semiconductor structures 530 and 540, e.g., the passivation function of the semiconductor substrate 510, may be difficult to maintain due to the damage D, so that a characteristic of the photovoltaic device may be deteriorated.

However, compared to the silicon nitride layer 560 according to the comparative example, the second silicon nitride layer 162 (e.g., the top or outer layer of the silicon nitride or gap insulation layer 160) according to an embodiment may have superior resistance to an alkaline solution, so that no damage may be generated.

To remove the damage D from the silicon nitride layer 560, e.g., the gap insulation layer, of the photovoltaic device according to the above-described comparative example, a process of removing the silicon nitride layer 560 and then forming a new insulation layer may be provided after the uneven or textured pattern R′ is formed on the second surface of the semiconductor substrate 510 and before the process of FIG. 5C is performed. However, according to an embodiment, little or no damage may be generated in the silicon nitride layer 160, e.g., the gap insulation layer of the photovoltaic device, the above-described process is not needed. Accordingly, the photovoltaic device according to an embodiment may be prepared by a more efficient method.

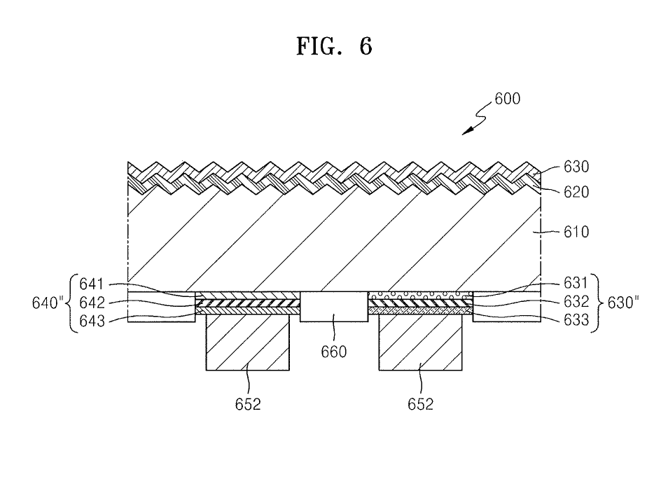

FIG. 6 illustrates a cross-sectional view of a photovoltaic device 600 according to an embodiment.

Referring to FIG. 6, the photovoltaic device 600 according to the present embodiment may include a semiconductor substrate 610, a passivation layer 620 and an anti-reflection layer 630 on a second, e.g., front, surface of the semiconductor substrate 610, a first semiconductor structure 630″ (of a first conductive type) and a second semiconductor structure 640″ (of a second conductive type) on a first, e.g., back, surface of the semiconductor substrate 610, first and second electrodes 651 and 652 respectively on the first and second semiconductor structures 630 and 640, and a gap insulation layer 660 between the first and second semiconductor structures 630 and 640.

The photovoltaic device 600 according to the present embodiment is different from the photovoltaic device 100 of the previous embodiment (see FIG. 1) in that a silicon nitride layer that is the gap insulation layer 660 may be formed as a single layer.

As noted above, the gap insulation layer 660 may be formed as a single layer. Thus, an interface therein may not clearly exist. For example, a silicon:nitrogen ratio of the gap insulation layer 660 may be continuous along a thickness direction thereof For example, a lower area of the gap insulation layer 660, e.g., an area close or proximate to the semiconductor substrate 610, may have substantially the same composition as that of the first gap insulation layer 161 described with reference to FIG. 1. Also, an upper area of the gap insulation layer 660, e.g., an area far from or distal to the semiconductor substrate 610, may have substantially the same composition as that of the second gap insulation layer 162 described with reference to FIG. 1. Thus, the structure of the photovoltaic device 600 of the present embodiment may be substantially the same as that of the photovoltaic device 100 of FIG. 1. The photovoltaic device 600 of the present embodiment may be manufactured through substantially the same operations as those of the manufacturing method described with reference to FIGS. 2 and 3A through 3K.

In the photovoltaic device 100 of FIG. 1 and the photovoltaic device 600 of FIG. 6, the interfaces of the gap insulation layers 160 and 660 may be controlled by a process of forming a silicon nitride layer on the second surfaces of the semiconductor substrates 110 and 610. For example, the existence of interface may be controlled by adjusting a flow rate of a gas that is a supply source of silicon and a gas that is a supply source of nitrogen, and a condition such as time for performing PE-CVD.

By way of summation and review, a photovoltaic device may have a structure in which an electrode is provided at each of a front surface (that is a light-receiving surface) and a back surface. When an electrode is provided at the front surface, a light receiving area may be decreased by as much as an area of the electrode. Thus, a back contact structure in which electrodes are provided only on a back surface may be used.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photovoltaic device, comprising:
a semiconductor substrate having a first surface and a second surface opposite to the first surface;
a silicon nitride gap insulation layer on the first surface of the semiconductor substrate, a portion of the gap insulation layer proximate to the semiconductor substrate having a silicon:nitrogen ratio different from a silicon:nitrogen ratio in a portion of the gap insulation layer distal to the semiconductor substrate;
a semiconductor structure on the first surface of the semiconductor substrate; and
an electrode on the semiconductor structure.

2. The device as claimed in claim 1, wherein:
the portion of the gap insulation layer proximate to the semiconductor substrate has a refractive index of about 1.98 or greater, and
the portion of the gap insulation layer distal to the semiconductor substrate has a refractive index of about 1.96 or less.

3. The device as claimed in claim 1, wherein the silicon:nitrogen ratio of the portion of the gap insulation layer proximate to the semiconductor substrate is greater than the silicon:nitrogen ratio of the portion of the gap insulation layer distal to the semiconductor substrate.

4. The device as claimed in claim 3, wherein:
the silicon:nitrogen ratio of the portion of the gap insulation layer proximate to the semiconductor substrate is 0.75 or higher, and
the silicon:nitrogen ratio of the portion of the gap insulation layer distal to the semiconductor substrate is less than 0.75.

5. The device as claimed in claim 3, wherein the silicon:nitrogen ratio of the gap insulation layer is continuous along a thickness direction thereof.

6. The device as claimed in claim 1, wherein the gap insulation layer includes:
a first gap insulation layer on the first surface of the semiconductor substrate, and
a second gap insulation layer on the first gap insulation layer, the first gap insulation layer being between the second gap insulation layer and the semiconductor substrate.

7. The device as claimed in claim 6, wherein the first gap insulation layer has a silicon:nitrogen ratio greater than a silicon:nitrogen ratio of the second gap insulation layer.

8. The device as claimed in claim 7, wherein:
the silicon:nitrogen ratio of the first gap insulation layer is 0.75 or greater, and
the silicon:nitrogen ratio of the second gap insulation layer is less than 0.75.

9. The device as claimed in claim 6, wherein:
the first gap insulation layer has a refractive index of about 1.98 or greater, and
the second gap insulation layer has a refractive index of about 1.96 or less.

10. The device as claimed in claim 1, further comprising at least one of a passivation layer and an antireflection layer on the second surface of the semiconductor substrate.

11. A method of manufacturing a photovoltaic device, the method comprising:
providing a semiconductor substrate;
forming a silicon nitride gap insulation layer on a first surface of the semiconductor substrate such that a portion of the gap insulation layer proximate to the semiconductor substrate has a silicon:nitrogen ratio different from a silicon:nitrogen ratio in a portion of the gap insulation layer distal to the semiconductor substrate.

12. The method as claimed in claim 11, wherein:
the portion of the gap insulation layer proximate to the semiconductor substrate has a refractive index of about 1.98 or greater, and
the portion of the gap insulation layer distal to the semiconductor substrate has a refractive index of about 1.96 or less.

13. The method as claimed in claim 11, wherein the silicon:nitrogen ratio of the portion of the gap insulation layer proximate to the semiconductor substrate is greater than the silicon:nitrogen ratio of the portion of the gap insulation layer distal to the semiconductor substrate.

14. The method as claimed in claim 13, wherein:
the silicon:nitrogen ratio of the portion of the gap insulation layer proximate to the semiconductor substrate is 0.75 or greater, and
the silicon:nitrogen ratio of the portion of the gap insulation layer distal to the semiconductor substrate is less than 0.75.

15. The method as claimed in claim 13, wherein the silicon:nitrogen ratio of the gap insulation layer is continuous along a thickness direction thereof.

16. The method as claimed in claim 11, wherein forming the gap insulation layer includes:
forming a first gap insulation layer on the first surface of the semiconductor substrate, and
forming a second gap insulation layer on the first gap insulation layer such that the first gap insulation layer is between the second gap insulation layer and the semiconductor substrate.

17. The method as claimed in claim 16, wherein the first gap insulation layer has a silicon:nitrogen ratio greater than a silicon:nitrogen ratio of the second gap insulation layer.

18. The method as claimed in claim 17, wherein:
the silicon:nitrogen ratio of the first gap insulation layer is 0.75 or greater, and
the silicon:nitrogen ratio of the second gap insulation layer is less than 0.75.

19. The method as claimed in claim 16, wherein:
the first gap insulation layer has a refractive index of about 1.98 or greater, and
the second gap insulation layer has a refractive index of about 1.96 or less.

20. The method as claimed in claim 11, further comprising forming at least one of a passivation layer and an antireflection layer on a second surface of the semiconductor substrate, the second surface being opposite to the first surface.
